(19) United States
(12) Patent Application Publication
(10) Pub. No.: US 2023/0408604 A1
(43) Pub. Date: Dec. 21, 2023

(54) SENSOR OUTPUT COMPENSATION CIRCUIT

(71) Applicant: Murata Manufacturing Co., Ltd., Nagaokakyo-shi (JP)

(72) Inventor: Aritsugu YAJIMA, Nagaokakyo-shi (JP)

(21) Appl. No.: 18/240,952

(22) Filed: Aug. 31, 2023

Related U.S. Application Data
(63) Continuation of application No. PCT/JP2022/010724, filed on Mar. 10, 2022.

(30) Foreign Application Priority Data
Mar. 31, 2021 (JP) 2021-061404

(51) Int. Cl. G01R 33/00; G01R 33/09

(52) U.S. Cl. CPC G01R 33/0082; G01R 33/098

(57) ABSTRACT

A sensor output compensation circuit includes a linearity compensation circuit to adjust linearity of a sensor output by changing a resistance value of a first variable resistor, a compensation circuit to adjust sensitivity temperature characteristics of a sensor output by changing a resistance value of a second variable resistor, and a compensation circuit to adjust temperature characteristics of an offset voltage of the sensor output by inputting a reference voltage to a reference voltage terminal of an operational amplifier of an amplifier circuit for compensation.

### CROSS REFERENCE TO RELATED APPLICATIONS

This application claims the benefit of priority to Japanese Patent Application No. 2021-061404 filed on Mar. 31, 2021 and is a Continuation Application of PCT Application No. PCT/JP2022/010724 filed on Mar. 10, 2022. The entire contents of each application are hereby incorporated herein by reference.

### BACKGROUND OF THE INVENTION

### 1. Field of the Invention

The present invention relates to a sensor output compensation circuit that adjusts an output of a sensor in which sensor components are bridge-connected.

### 2. Description of the Related Art

Conventionally, as this kind of sensor output compensation circuit, for example, a sensor circuit disclosed in Japanese Unexamined Patent Application Publication No. 2003-248017 is known.

This sensor circuit includes a detection unit (preamplifier unit) that includes a sensor element, a power supply unit (application circuit for sensor) that defines a power supply for the detection unit, and an amplifier unit (main amplifier unit) that amplifies a signal from the detection unit. The application circuit for sensor includes a constant-voltage circuit, and includes a sensitivity temperature compensation circuit and a non-linearity compensation circuit as sensor output compensation circuits. A constant voltage from the constant-voltage circuit is input to the sensitivity temperature compensation circuit, and output signals of the sensitivity temperature compensation circuit and the non-linearity compensation circuit are added up and become an input signal to the preamplifier unit. From the preamplifier unit, a signal corresponding to a physical quantity detected by the sensor element is output. The non-linearity compensation circuit is disposed within a feedback circuit for feeding back a sensor circuit (main amplifier unit) output.

Furthermore, conventionally, as this kind of sensor output compensation circuit, for example, an amplifier circuit for magnetoresistive element disclosed in Japanese Unexamined Patent Application Publication No. 11-194160 is known.

This amplifier circuit for magnetoresistive element includes a magnetoresistive element in which four ferromagnetic magnetoresistive element patterns are bridge-connected, and a differential amplifier circuit is connected to a pair of output terminals of the magnetoresistive element to differentially amplify an output voltage of the magnetoresistive element. The differential amplifier circuit is provided with an offset adjustment circuit that sets a midpoint potential of the amplified output voltage to a predetermined potential by a variable resistor, and a temperature compensation circuit that compensates for fluctuation of an amplitude of the output voltage caused by a temperature change is provided as a sensor output compensation circuit in a stage subsequent to the differential amplifier circuit.

However, the conventional non-linearity compensation circuit disclosed in Japanese Unexamined Patent Application Publication No. 2003-248017 is disposed within a feedback circuit for feeding back a sensor circuit output, and compensates for non-linearity by feeding back an output of the sensor circuit. Due to the feedback, a response of the circuit is delayed, and non-linearity compensation of a sensor output is delayed accordingly. Furthermore, since the output signals of the sensitivity temperature compensation circuit and the non-linearity compensation circuit are added up and input to the preamplifier unit, an adding circuit is needed, and a scale of the sensor output compensation circuit becomes large.

Furthermore, the conventional temperature compensation circuit disclosed in Japanese Unexamined Patent Application Publication No. 11-194160 uses a thermistor element as a resistor for temperature compensation, and therefore can perform only temperature compensation that depends on thermistor characteristics. Accordingly, a temperature range in which temperature compensation can be performed is limited, and temperature fluctuation in a wider range cannot be compensated for, and therefore there is a limit on temperature compensation of a sensor output. Furthermore, since there are variations in characteristics of the thermistor element, the variations appear in temperature compensation characteristics, leaving a problem in accuracy of temperature compensation. Furthermore, since the thermistor element is used in the temperature compensation circuit, high integration is difficult, and it is difficult to reduce size and cost of the temperature compensation circuit.

### SUMMARY OF THE INVENTION

Preferred embodiments of the present invention provide sensor output compensation circuits that are each able to perform sensor output non-linearity compensation at a high speed, maintain a circuit scale of the sensor output compensation circuit small, perform sensitivity temperature compensation of a sensor output for temperature fluctuation in a wider range with high accuracy, reduce size and cost of the circuit, and easily perform temperature compensation of an offset voltage of a sensor output accurately.

A sensor output compensation circuit according to a preferred embodiment of the present invention includes a differential amplifier circuit to amplify, as a sensor output, a differential voltage between detection voltages appearing in a pair of detection signal output terminals of a sensor in which sensor components whose resistance values change in accordance with a detected physical quantity are bridge-connected, an amplifier circuit to adjust an output of the differential amplifier circuit, and a linearity compensation circuit for the sensor output to change an amplification rate of the amplifier circuit to an amplification rate that cancels distortion appearing with non-linearity in the sensor output in response to a change of a physical amount.

According to this configuration, distortion that appears with non-linearity in a sensor output in response to a change in physical quantity is compensated for since the linearity compensation circuit changes an amplification rate of the amplifier circuit that adjusts an output of the differential amplifier circuit to an amplification rate that cancels the distortion. Therefore, the distortion of the sensor output can be compensated for without feeding back the sensor output unlike the conventional non-linearity compensation circuit disclosed in Japanese Unexamined Patent Application Publication No. 2003-248017. Accordingly, a circuit response speed becomes high, and sensor output non-linearity compensation is performed at a high speed. Furthermore, an adding circuit is not needed in the sensor output compensation circuit unlike the conventional art, and therefore a circuit scale of the sensor output compensation circuit can be maintained small.

A sensor output compensation circuit according to a preferred embodiment of the present invention includes a differential amplifier circuit to amplify, as a sensor output, a differential voltage between detection voltages appearing in a pair of detection signal output terminals of a sensor in which sensor components whose resistance values change in accordance with a detected physical quantity are bridge-connected, an amplifier circuit to adjust an output of the differential amplifier circuit, a temperature sensor circuit to detect an ambient temperature, and a sensor sensitivity temperature characteristic compensation circuit to change an amplification rate of the amplifier circuit to an amplification rate that cancels fluctuations appearing in sensitivity of the sensor output in response to a change of the ambient temperature detected by the temperature sensor circuit on a basis of the ambient temperature.

According to this configuration, fluctuations appearing in the sensitivity of a sensor output in response to a change in ambient temperature are compensated for by changing the amplification rate of the amplifier circuit to adjust an output of the differential amplifier circuit to an amplification rate that cancels the fluctuation by the sensor sensitivity temperature characteristic compensation circuit. Therefore, a temperature range in which temperature compensation can be performed is not limited, and sensitivity temperature compensation of a sensor output can be performed for an ambient temperature fluctuation in a wider range, unlike the conventional temperature compensation circuit disclosed in Japanese Unexamined Patent Application Publication No. 11-194160 that can perform only temperature compensation that depends on thermistor characteristics. Furthermore, variations among thermistor elements do not appear in temperature compensation characteristics unlike the conventional art, and sensitivity temperature compensation can be performed with high accuracy. Furthermore, since the sensor output compensation circuit does not need a thermistor element in a temperature compensation circuit, integration of the sensor output compensation circuit is possible, and therefore size and cost of the sensor output compensation circuit can be reduced.

A sensor output compensation circuit according to a preferred embodiment of the present invention includes a differential amplifier circuit to amplify, as a sensor output, a differential voltage between detection voltages appearing in a pair of detection signal output terminals of a sensor in which sensor elements whose resistance values change in accordance with a detected physical quantity are bridge-connected, an amplifier circuit to adjust an output of the differential amplifier circuit, a temperature sensor circuit to detect an ambient temperature, and an offset temperature characteristic compensation circuit to cause a reference voltage that cancels fluctuations of an offset voltage of the sensor output appearing in response to a change of the ambient temperature to be input to a reference voltage terminal of the amplifier circuit for compensation by referring to the ambient temperature detected by the temperature sensor circuit.

According to the present configuration, fluctuations of an offset voltage of a sensor output that appear in response to a change in ambient temperature are canceled since the amplifier circuit to adjust an output of the differential amplifier circuit amplifies an output of the differential amplifier circuit based on a reference voltage input to a reference voltage terminal from the offset temperature characteristic compensation circuit. Therefore, temperature compensation of an offset voltage of a sensor output can be easily and accurately performed unlike the conventional offset adjustment circuit disclosed in Japanese Unexamined Patent Application Publication No. 11-194160 that performs offset adjustment of a sensor output just by adjusting a midpoint potential of a differential amplifier circuit output by a variable resistor.

Therefore, according to preferred embodiments of the present invention, sensor output compensation circuits that are each able to perform sensor output non-linearity compensation at a high speed, maintain a circuit scale of the sensor output compensation circuit small, perform sensitivity temperature compensation of a sensor output for temperature fluctuation in a wider range with high accuracy, reduce size and cost of the circuit, and easily perform temperature compensation of an offset voltage of a sensor output accurately are provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram illustrating a configuration of a sensor output compensation circuit according to a preferred embodiment of the present invention.

FIG. 2 is a circuit diagram for explaining a function of a linearity compensation circuit of the sensor output compensation circuit illustrated in FIG. 1.

FIG. 3A is a graph illustrating how a sensor output changes in response to a magnetic field, and FIG. 3B is a graph illustrating distortion of a sensor output that appears with non-linearity.

FIG. 4A is a graph illustrating a control signal that is output to change a resistance value of a variable resistor R4 from the linearity compensation circuit, and FIG. 4B is a graph illustrating distortion of a sensor output after compensation by the linearity compensation circuit.

FIG. 5 is a circuit diagram for explaining a function of a TCS compensation circuit of the sensor output compensation circuit illustrated in FIG. 1.

FIG. 6A is a graph illustrating a result of measurement of temperature characteristics concerning sensitivity of a sensor output, and FIG. 6B is a graph illustrating how a fluctuation rate of an output voltage output from the sensor output compensation circuit changes in response to an ambient temperature.

FIG. 7A is a graph illustrating temperature characteristics concerning sensitivity of a sensor output after compensation by the TCS compensation circuit, and FIG. 7B is a graph illustrating voltage characteristics of an ambient temperature used in the TCS compensation.

FIG. 8 is a circuit diagram for explaining a function of an TCO compensation circuit of the sensor output compensation circuit illustrated in FIG. 1.

FIG. 9A is a graph showing temperature characteristics of a fluctuation rate of an offset voltage, and FIG. 9B is a graph illustrating temperature characteristics of a fluctuation rate of an offset voltage after compensation by the TCO compensation circuit.

### DETAILED DESCRIPTION OF THE PREFERRED EMBODIMENTS

Preferred embodiments of the present invention will be described in detail below with reference to the drawings.

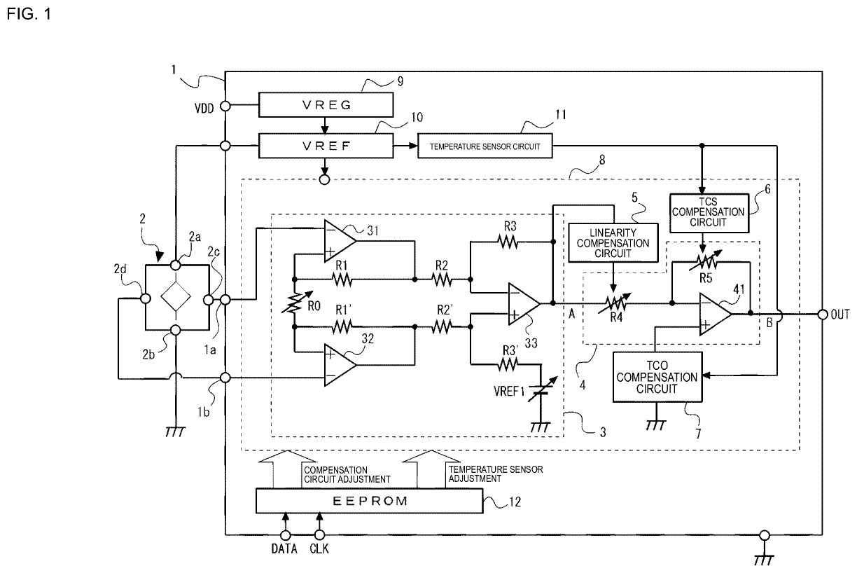

FIG. 1 is a circuit diagram illustrating a configuration of a sensor output compensation circuit according to a preferred embodiment of the present invention.

The sensor output compensation circuit is a circuit to which an output of a Tunneling Magneto-Resistive (TMR) sensor 2 is input and performs various kinds of compensation of the sensor output, and is integrated to become a sensor output compensation IC 1. The TMR sensor 2 is configured such that TMR elements whose resistance values change depending on a magnetic field, which is a detected physical quantity, are bridge-connected, and operates upon application of a predetermined voltage between a pair of power supply terminals 2a and 2b. A magnetic field detected by the TMR sensor 2 appears as a voltage difference between a pair of detection signal output terminals 2c and 2d of the TMR sensor 2 and is provided as a sensor output to signal input terminals 1a and 1b of the sensor output compensation IC 1. Such a TMR sensor 2 is, for example, used to monitor an electric current supplied to a motor of a hybrid vehicle.

The various kinds of compensation performed by the sensor output compensation IC 1 include, for example, linearity compensation, sensitivity compensation, sensitivity temperature characteristic compensation (temperature coefficient sensitivity (TCS) compensation: hereinafter referred to as TCS compensation), offset compensation, and offset temperature characteristic compensation (temperature characteristic of offset (TCO) compensation: hereinafter referred to as TCO compensation) of a sensor output. Furthermore, the various kinds of compensation also include, for example, compensation for variations in these kinds of compensation among individual TMR sensors 2.

The linearity compensation is to assure linearity of a sensor output by removing a non-linearity component of the sensor output. The offset compensation is to cancel an offset voltage appearing in the pair of detection signal output terminals 2c and 2d in a case where no magnetic field is detected by the TMR sensor 2. The TCO compensation is to cancel a temperature fluctuation of an offset voltage. The sensitivity compensation is to cancel variations concerning sensitivity among individual TMR sensors 2. The sensitivity of the TMR sensor 2 is a value obtained by subtracting an offset voltage from a rated output voltage of the sensor output compensation IC 1 to obtain an output span voltage and dividing the output span voltage by a rated magnetic field and denotes a change in output voltage per unit magnetic field. The TCS compensation cancels a temperature fluctuation of a temperature coefficient sensitivity that represents how much the output span voltage changes at a maximum at a compensated temperature.

The sensor output compensation IC 1 includes a differential amplifier circuit 3, which is an instrumentation amplifier, and an amplifier circuit 4 to adjust an output of the differential amplifier circuit 3. The differential amplifier circuit 3 includes operational amplifiers 31 and 32 that amplify detection voltages appearing in the pair of detection signal output terminals 2c and 2d of the TMR sensor 2 and an operational amplifier 33 that differentially amplifies the amplified detection voltages. A differential voltage between the detection voltages appearing in the pair of detection signal output terminals 2c and 2d is handled as a substantial sensor output. The differential amplifier circuit 3 outputs an output A obtained by amplifying the sensor output at an amplification rate α expressed by the following formula (1) where R0, R1, R2, R3, R1′, R2′, and R3 represent resistors connected to the operational amplifiers 31 to 33 and resistance values thereof as illustrated in FIG. 1.

α=(R3/R2)×{1+(2×R1)/R0} (1)

Note that R1=R1′, R2=R2′, R3=R3′, and R0 is a variable resistor.

Sensitivity of the sensor output is adjusted by changing the variable resistor R0, and variations among individual TMR sensors 2 are compensated for. Furthermore, a variable voltage source VREF1 is connected to a non-inverting input terminal of the operational amplifier 33 with the resistor R3′ interposed therebetween. The offset voltage of the sensor output is adjusted by changing an output voltage of the variable voltage source VREF1 so that an output voltage VOUT appearing in an output terminal OUT of the sensor output compensation IC 1 becomes zero in a case where no magnetic field is detected by the TMR sensor 2.

The amplifier circuit 4 includes an operational amplifier 41 to which a variable resistor R4 and a variable resistor R5 are connected, and outputs an output B obtained by inverting amplification of the output A of the differential amplifier circuit 3 to the output terminal OUT of the sensor output compensation IC 1 as the output voltage VOUT. As a result, the sensor output is amplified at an amplification rate β expressed by the following formula (2).

β=α×(R5/R4)=(R3/R2)×{1+(2×R1)/R0}×(R5/R4) (2)

An amplification rate (R5/R4) of the amplifier circuit 4 is changed by changing a resistance value of the connected variable resistor R4 or R5. In the present preferred embodiment, resistance values of the variable resistors R4 and R5 are changed by switching connection between a plurality of resistors (not illustrated) by a plurality of switches (not illustrated) and thus changing a combined resistance value of the plurality of resistors.

The sensor output compensation IC 1 according to the present preferred embodiment includes a linearity compensation circuit 5 that adjusts linearity of the sensor output, a TCS compensation circuit 6 that adjusts a temperature coefficient sensitivity of the sensor output, and an TCO compensation circuit 7 that adjusts temperature characteristics of an offset voltage of the sensor output. The differential amplifier circuit 3, the amplifier circuit 4, the linearity compensation circuit 5, the TCS compensation circuit 6, and the TCO compensation circuit 7 define a compensation block 8 of the sensor output compensation IC 1.

Furthermore, the sensor output compensation IC 1 includes a regulator circuit (VREG) 9, a reference voltage circuit (VREF) 10, and a temperature sensor circuit 11. The regulator circuit 9 generates a base voltage from a voltage input to a power supply terminal VDD. The reference voltage circuit 10 generates reference voltages of various values used in the TCS compensation circuit 6, the TCO compensation circuit 7, and the like and a power supply voltage to be applied to the TMR sensor 2 from the base voltage generated by the regulator circuit 9. The temperature sensor circuit 11 detects an ambient temperature by a diode and outputs, as a voltage, the detected ambient temperature to the TCS compensation circuit 6 and the TCO compensation circuit 7. Since the TMR sensor 2 and the sensor output compensation IC 1 are disposed close to each other, the ambient temperature detected by the temperature sensor circuit 11 is detected as an ambient temperature of the TMR sensor 2.

Furthermore, the sensor output compensation IC 1 includes an EEPROM 12 whose storage contents can be rewritten by a user. Into this EEPROM 12, setting data is written from a data terminal DATA by the user. In accordance with this setting data, compensation operations performed by the various kinds of compensation circuits in the compensation block 8 are set and adjusted, and temperature detection in the temperature sensor circuit 11 is set and adjusted.

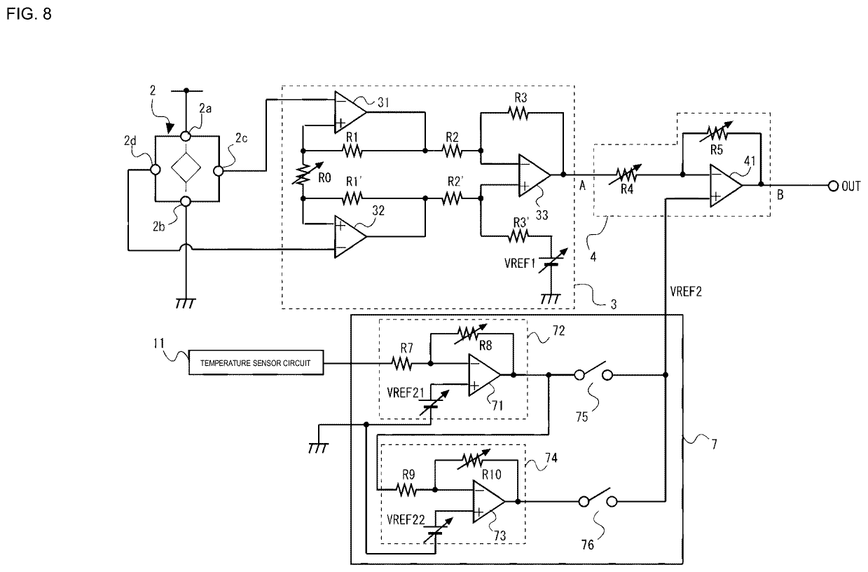

In the present preferred embodiment, the compensation performed by the linearity compensation circuit 5 and the TCS compensation circuit 6 is performed by changing the amplification rate (R5/R4) of the amplifier circuit 4 as described later. The amplification rate (R5/R4) is changed by switching a state of connection between a plurality of resistors that define the variable resistors R4 and R5 by a plurality of switches in accordance with the setting data written into the EEPROM 12. The compensation performed by the TCO compensation circuit 7 is also performed by switching a state of connection of switches 75 and 76 (see FIG. 8), which will be described later, in accordance with the setting data written into the EEPROM 12. Furthermore, the temperature sensor circuit 11 is adjusted to output a voltage of 1 [V] when the ambient temperature is, for example, about 25° C. in accordance with the setting data written into the EEPROM 12.

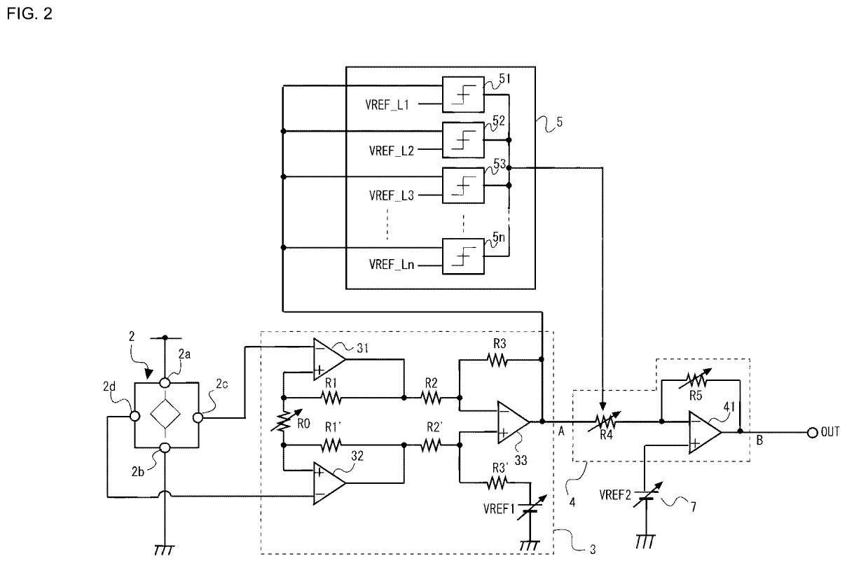

FIG. 2 is a circuit diagram for explaining a function of the linearity compensation circuit 5 of the sensor output compensation IC 1 illustrated in FIG. 1. In FIG. 2, the same or corresponding portions to those in FIG. 1 are denoted by the same reference signs, and description thereof is omitted.

The linearity compensation circuit 5 includes a plurality of comparators 51, 52, 53, . . . , and 5n. An output voltage of the differential amplifier circuit 3 is input to one input terminal of each of the comparators 51, 52, 53, . . . , and 5n, and predetermined reference voltages VREF_L1, VREF_L2, VREF_L3, . . . , and VREF_Ln output from the reference voltage circuit are input to the other input terminals of the comparators 51, 52, 53, . . . , and 5n. The reference voltages VREF_L1, VREF_L2, VREF_L3, . . . , and VREF_Ln correspond to sensor outputs according to magnetic fields that cause predetermined distortions appearing with non-linearity in sensor outputs, and are set in advance on the basis of the setting data written into the EEPROM 12.

The linearity compensation circuit 5 changes the amplification rate (R5/R4) of the amplifier circuit 4 to an amplification rate that cancels distortion by switching a plurality of switches that define the variable resistor R4 and thus changing a resistance value of the variable resistor R4 in accordance with a result of comparison between these plurality of reference voltages and an output voltage of the differential amplifier circuit 3.

Although an example in which the amplification rate (R5/R4) of the amplifier circuit 4 is changed by switching the plurality of switches that define the variable resistor R4 and thus changing the resistance value of the variable resistor R4 is described here, the amplification rate (R5/R4) of the amplifier circuit 4 may be changed by switching a plurality of switches that define the variable resistor R5 and thus changing a resistance value of the variable resistor R5.

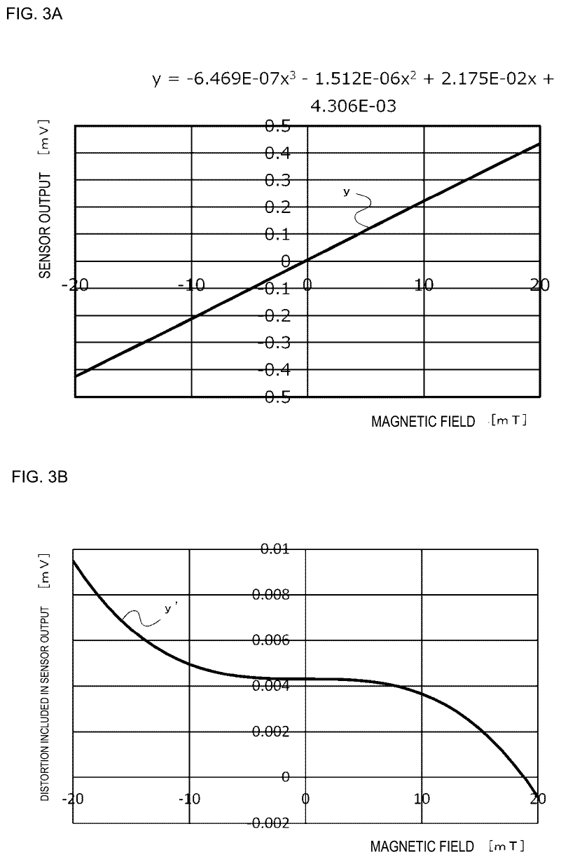

FIG. 3A is a graph illustrating an example of a relationship between a magnetic field applied to the TMR sensor 2 and a sensor output appearing as a differential voltage between the detection signal output terminals 2c and 2d in a case where the magnetic field is applied to the TMR sensor 2. The horizontal axis of the graph represents a magnetic field [mT] applied to the TMR sensor 2, and the vertical axis of the graph represents a sensor output [mV]. Furthermore, the characteristic line y represents how the sensor output changes in response to a magnetic field when the ambient temperature of the sensor output compensation IC 1 is, for example, about 25° C., and indicates linearity characteristics of the sensor output. The characteristic line y is expressed as a polynomial of the following formula (3) where a magnetic field x is a variable.

y=−6.469e^{-0.7}x³−1.512e^{-0.6}s²+2.175e^{-0.2}x+4.306e^{-0.3} (3)

Although the characteristic line y appears to be linear in FIG. 3A, the characteristic line y includes non-linear components indicated by the first and second terms in the right-hand side of formula (3), and when a linear component in the third term of the right-hand side is excluded, the relationship between the magnetic field and the sensor output is expressed by the graph illustrated in FIG. 3B. The horizontal axis of the graph represents a magnetic field [mT] applied to the TMR sensor 2, but the vertical axis of the graph represents a sensor output [mV] excluding the linear component. The characteristic line y′ represents distortion of the sensor output appearing with non-linearity. This distortion affects magnetic field detection accuracy of the TMR sensor 2, and therefore this distortion is compensated for by the linearity compensation circuit 5.

The graph shows that the distortion exists in a magnetic field region of approximately +8 [mT] or more and in a magnetic field region of approximately −8 [mT] or less, the distortion is cancelled by changing the amplification rate of the amplifier circuit 4 by the linearity compensation circuit 5 when a sensor output for a predetermined magnetic field is obtained in these magnetic field regions.

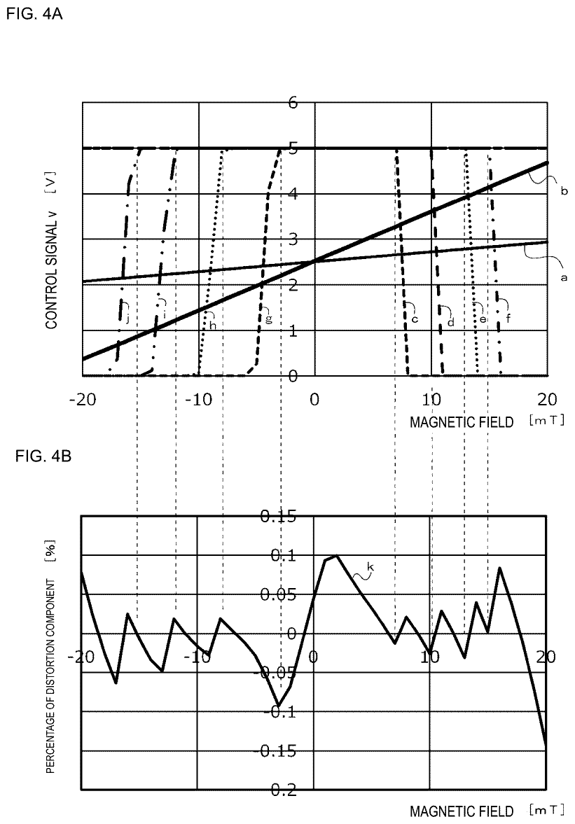

FIG. 4A is a graph illustrating an example of a control signal v provided to each switch of the variable resistor R4 from the linearity compensation circuit 5. The horizontal axis of the graph represents a magnetic field [mT] applied to the TMR sensor 2, and the vertical axis of the graph represents a voltage [V] of the control signal v. The characteristic line a represents a magnetic field change of an input voltage input to the input terminals 1a and 1b of the sensor output compensation IC 1, and the characteristic line b represents a magnetic field change of the output voltage VOUT output to the output terminal out of the sensor output compensation IC 1. Furthermore, the characteristic lines c, d, e, and f represent control signals v1, v2, v3, and v4 to correct distortions of sensor outputs in a positive-side magnetic field of approximately +8 [mT] or more illustrated in FIG. 3B, and the characteristic lines g, h, i, and j represent control signals v5, v6, v7, and v8 to correct distortions of sensor outputs in a negative-side magnetic field of approximately −8 [mT]. The control signals v1 to v8 change between a high level of approximately +5 [V] and a low level of approximately 0 [V], and for example, when the control signals v1 to v8 change to the low level, the switches sw1 to sw8 are controlled to close.

In the graph, as for the distortion of the sensor output in the magnetic field region of approximately +8 [mT] or more, in the case of a magnetic field of approximately +7 [mT], the switch sw1 is controlled to close by changing the control signal v1 expressed by the characteristic line c to the low level, and thus the resistance value of the variable resistor R4 is changed such that the amplification rate of the amplifier circuit 4 is changed to an amplification rate that cancels the distortion in this magnetic field. Furthermore, the switch sw2 is controlled to close by changing the control signal v2 expressed by the characteristic line d to the low level in the case of a magnetic field of approximately +10 [mT], the switch sw3 is controlled to close by changing the control signal v3 expressed by the characteristic line e to the low level in the case of a magnetic field of approximately +13[mT], and the switch sw4 is controlled to close by changing the control signal v4 expressed by the characteristic line f to the low level in the case of a magnetic field of approximately +15 [mT], and thus the resistance value of the variable resistor R4 is changed, and the amplification rate of the amplifier circuit 4 is changed to an amplification rate that cancels the distortion in each magnetic field.

Similarly, as for the distortion of the sensor output in the magnetic field region of approximately −8 [mT], the switches sw5 to sw8 are controlled to close by the control signals v5 to v8 expressed by the characteristic lines g to j, and thus the resistance value of the variable resistor R4 is changed such that the amplification rate of the amplifier circuit 4 is changed to an amplification rate that cancels the distortion in each magnetic field.

FIG. 4B is a graph illustrating distortion of the sensor output after non-linearity of the sensor output is compensated for by such resistance value control of the variable resistor R4 by the linearity compensation circuit 5. The horizontal axis of the graph represents a magnetic field [mT] applied to the TMR sensor 2, and the vertical axis of the graph represents a percentage [9 6] of a distortion component included in the output voltage VOUT output to the output terminal out of the sensor output compensation IC 1. Furthermore, the characteristic line k represents fluctuation characteristics of the distortion component included in the output voltage VOUT with respect to a magnetic field change.

Although the distortion of the sensor output in the magnetic field region of approximately +8 [mT] or more decreases rightward as the magnetic field increases as illustrated in FIG. 3B, it can be understood from the characteristic line k that a percentage of a distortion component is increased rightward to cancel the decrease of the distortion illustrated in FIG. 3B by increasing the amplification rate of the amplifier circuit 4 at timings when the control signals v1, v2, v3, and v4 are sequentially changed to the low level in the magnetic fields of approximately +7 [mT], approximately +10 [mT], approximately +13 [mT], and approximately +15 [mT].

Although the distortion of the sensor output in the magnetic field region of approximately −8 [mT] or less increases leftward as the magnetic field decreases as illustrated in FIG. 3B, it can be similarly understood from the characteristic line k that a percentage of a distortion component is decreased leftward to cancel the increase of the distortion illustrated in FIG. 3B by decreasing the amplification rate of the amplifier circuit for compensation 4 at timings when the control signals v5 to v8 are sequentially changed to the low level in accordance with the decrease of the magnetic field.

In the positive-side magnetic field region, the percentage of the distortion component temporarily decreases rightward due to the original decrease of the distortion illustrated in FIG. 3B after increasing rightward. Furthermore, in the negative-side magnetic field region, the percentage of the distortion component temporarily increases leftward due to the original increase of the distortion illustrated in FIG. 3B after decreasing leftward. Therefore, although the characteristic line k fluctuates up and down in a zigzag manner as illustrated in FIG. 4B, a fluctuation width of the distortion component is maintained to be equal to or less than about ±0.1[%], for example, and linearity of the sensor output is assured.

As described above, with the sensor output compensation IC 1 according to the present preferred embodiment, the amplification rate of the amplifier circuit 4 is changed by switching connection between the plurality of resistors connected as the variable resistor R4 to the amplifier circuit 4 by control of the plurality of switches of the linearity compensation circuit 5 and thus changing a combined resistance value of the plurality of resistors. The switching of the switches is performed when the output voltage of the differential amplifier circuit 3 becomes a voltage corresponding to a sensor output according to a magnetic field that causes predetermined distortion as a result of comparison with the plurality of reference voltages VREF_L1, VREF_L2, VREF_L3, . . . , and VREF_Ln set in advance. By the switching of the switches, the amplification rate of the amplifier circuit 4 becomes an amplification rate that cancels predetermined distortion from the output of the differential amplifier circuit 3 in accordance with the output voltage of the differential amplifier circuit 3, and linearity of the sensor output is ensured.

That is, with the sensor output compensation IC 1 according to the present preferred embodiment, distortion appearing with non-linearity in a sensor output in response to a change of a magnetic field is compensated for since the amplification rate of the amplifier circuit 4 that adjusts an output of the differential amplifier circuit 3 is changed to an amplification rate that cancels the distortion by the linearity compensation circuit 5. Therefore, the distortion of the sensor output can be compensated for without feeding back the sensor output unlike the conventional non-linearity compensation circuit disclosed in Japanese Unexamined Patent Application Publication No. 2003-248017. Accordingly, a circuit response speed becomes high, and sensor output non-linearity compensation is performed at a high speed. Furthermore, an adding circuit is not needed in the sensor output compensation circuit unlike the conventional art, and therefore a circuit scale of the sensor output compensation IC 1 can be maintained small.

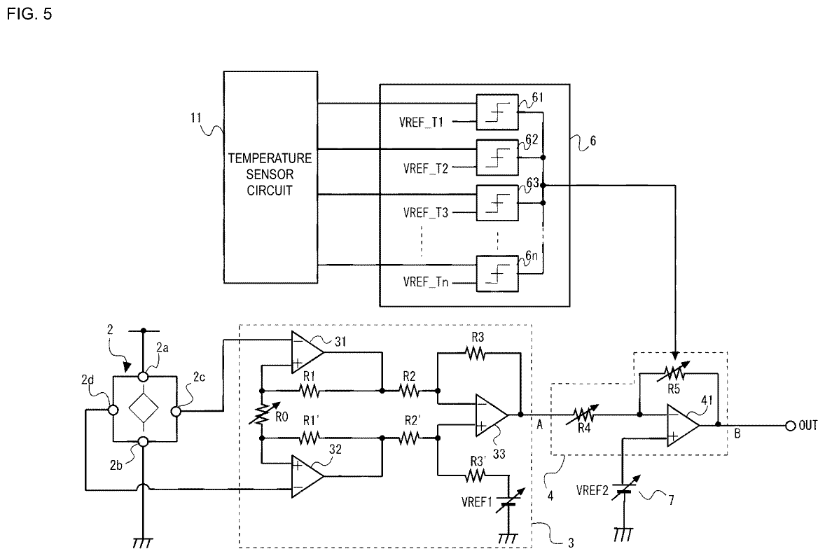

FIG. 5 is a circuit diagram for explaining a function of the TCS compensation circuit 6 of the sensor output compensation IC 1 illustrated in FIG. 1. In FIG. 5, the same or corresponding portions to those in FIG. 1 are denoted by the same reference signs, and description thereof is omitted.

The TCS compensation circuit 6 includes a plurality of comparators 61, 62, 63, . . . , and 6n. An ambient temperature detected as a voltage by the temperature sensor circuit 11 is input to one input terminal of each of the comparators 61, 62, 63, . . . , and 6n, and predetermined reference voltages VREF_T1, VREF_T2, VREF_T3, . . . , and VREF_Tn output from the reference voltage circuit 10 are input to the other input terminals of the comparators 61, 62, 63, . . . , and 6n. These reference voltages VREF_T1, VREF_T2, VREF_T3, . . . , and VREF_Tn correspond to voltages according to ambient temperatures that cause predetermined fluctuations in sensitivity of a sensor output and are set in advance based on the setting data written into the EEPROM 12.

The TCS compensation circuit 6 changes the amplification rate (R5/R4) of the amplifier circuit 4 to an amplification rate that cancels a fluctuation appearing in sensitivity of a sensor output in response to a change in ambient temperature by changing the resistance value of the variable resistor R5 by switching the plurality of switches that define the variable resistor R5 in accordance with a result of comparison between the plurality of reference voltages and an ambient temperature detected as a voltage by the temperature sensor circuit 11.

Although an example in which the amplification rate (R5/R4) of the amplifier circuit 4 is changed by switching the plurality of switches that define the variable resistor R5 and thus changing the resistance value of the variable resistor R5 is described here, the amplification rate (R5/R4) of the amplifier circuit 4 may be changed by switching the plurality of switches that define the variable resistor R4 and thus changing the resistance value of the variable resistor R4.

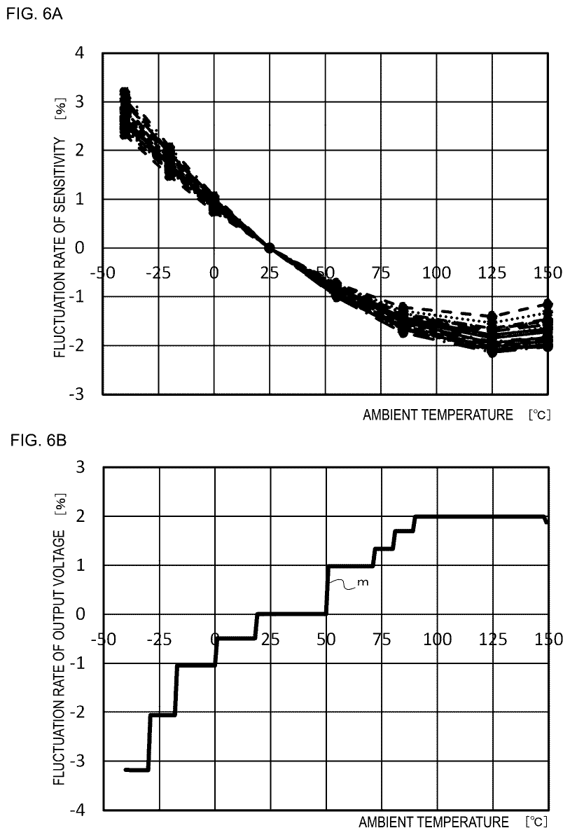

FIG. 6A is a graph illustrating a result of measurement of temperature characteristics concerning sensitivity of a sensor output performed on a plurality of TMR sensors 2. The horizontal axis of the graph represents an ambient temperature [° C.] of the TMR sensor 2, and the vertical axis of the graph represents a fluctuation rate [%] of sensitivity at each ambient temperature based on sensitivity of a sensor output at an ambient temperature of, for example, about 25° C. Furthermore, the characteristic lines represent sensitivity temperature characteristics of the plurality of TMR sensors 2.

As illustrated in the graph, in a temperature region in which the ambient temperature is lower than about 25° C., a fluctuation rate of sensitivity linearly increases to a positive side as the temperature decreases. On the other hand, in a temperature region in which the ambient temperature is higher than about 25° C., a fluctuation rate of sensitivity non-linearly increases to a negative side as the temperature increases.

FIG. 6B is a graph showing how much the output voltage VOUT of the sensor output compensation IC 1 has been fluctuated by changing the amplification rate of the amplifier circuit 4 in accordance with ambient temperatures that cause predetermined fluctuations in sensitivity based on the temperature characteristics of sensitivity illustrated in FIG. 6A. The horizontal axis of the graph represents an ambient temperature [° C.], and the vertical axis represents a fluctuation rate [%] of the output voltage VOUT. The characteristic line m represents how the fluctuation rate of the output voltage VOUT changes in response to the ambient temperature.

As indicated by the characteristic line m, in the temperature region in which the ambient temperature is lower than about 25° C., the fluctuation rate of the output voltage VOUT linearly decreases leftward to a negative side as the ambient temperature decreases to cancel the fluctuation rate of sensitivity that linearly increases leftward illustrated in FIG. 6A. Furthermore, in the temperature region in which the ambient temperature is higher than about 25° C., the fluctuation rate of the output voltage VOUT non-linearly increases rightward to a positive side as the ambient temperature increases to cancel the fluctuation rate of sensitivity that non-linearly decreases rightward illustrated in FIG. 6A.

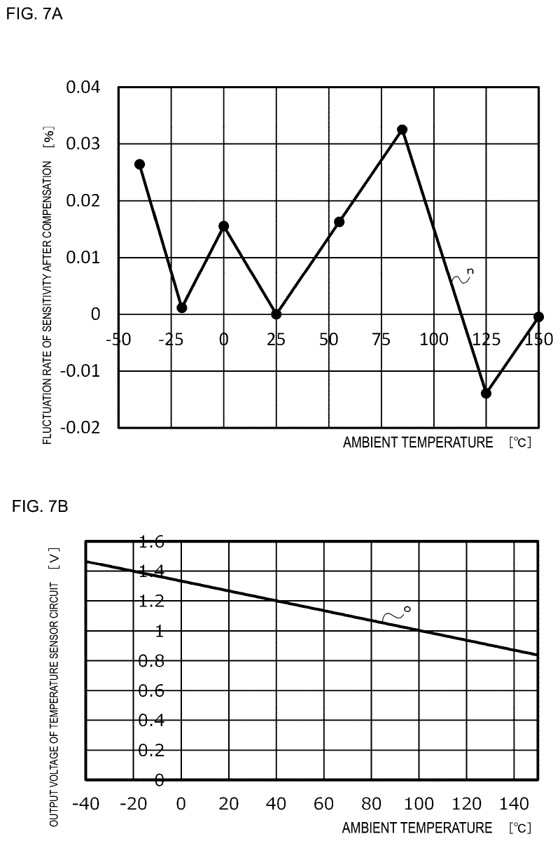

FIG. 7A is a graph illustrating temperature characteristics concerning sensitivity of a sensor output after the TCS compensation. The horizontal axis of the graph represents an ambient temperature [° C.] of the TMR sensor 2, and the vertical axis of the graph represents a fluctuation rate [%] of sensitivity at each ambient temperature based on sensitivity of a sensor output at an ambient temperature of, for example, about 25° C. The characteristic line n represents sensitivity temperature characteristics of a sensor output adjusted by the fluctuation rate of the output voltage VOUT illustrated in FIG. 6B. As illustrated in the graph, the fluctuation rate of sensitivity of the sensor output after the compensation falls within a small fluctuation width of about +0.04 [%] to about −0.02 [%].

FIG. 7B is a graph illustrating voltage characteristics of an ambient temperature used in the TCS compensation. The horizontal axis of the graph represents an ambient temperature [° C.] of the sensor output compensation IC 1, and the vertical axis represents an output voltage [V] of the temperature sensor circuit 11 at each ambient temperature. The characteristic line o represents temperature characteristics of the output voltage of the temperature sensor circuit 11.

As described above, with the sensor output compensation IC 1 according to the present preferred embodiment, the amplification rate of the amplifier circuit 4 is changed by switching connection between a plurality of resistors connected as the variable resistor R5 to the amplifier circuit 4 by control of the plurality of switches of the TCS compensation circuit 6 and thus changing a combined resistance value of the plurality of resistors. Furthermore, the switching of the switches is performed when an ambient temperature detected as a voltage by the temperature sensor circuit 11 becomes a voltage according to an ambient temperature that causes a predetermined fluctuation as a result of comparison with the plurality of reference voltages VREF_T1, VREF_T2, VREF_T3, . . . , and VREF_Tn set in advance. By this switching of the switches, the amplification rate of the amplifier circuit 4 becomes an amplification rate that cancels the predetermined fluctuation of sensitivity caused by an ambient temperature from an output of the differential amplifier circuit 3, and sensitivity temperature characteristics of a sensor output are adjusted.

That is, with the sensor output compensation IC 1 according to the present preferred embodiment, a fluctuation appearing in sensitivity of a sensor output in response to a change in ambient temperature is compensated for since the amplification rate of the amplifier circuit 4 that adjusts an output of the differential amplifier circuit 3 is changed to an amplification rate that cancels the fluctuation by the TCS compensation circuit 6. Therefore, a temperature range in which temperature compensation can be performed is not limited, and sensitivity temperature compensation of sensor output sensitivity can be performed for an ambient temperature fluctuation in a wider range, unlike the conventional temperature compensation circuit that can perform only temperature compensation that depends on thermistor characteristics disclosed in Japanese Unexamined Patent Application Publication No. 11-194160. Furthermore, variations among thermistor elements do not appear in temperature compensation characteristics unlike the conventional art, and sensitivity temperature compensation can be performed with high accuracy. Furthermore, since the sensor output compensation circuit does not need a thermistor element in a temperature compensation circuit, integration of the sensor output compensation circuit is possible, and therefore the size and cost of the sensor output compensation circuit can be reduced.

FIG. 8 is a circuit diagram for explaining a function of the TCO compensation circuit 7 of the sensor output compensation IC 1 illustrated in FIG. 1. In FIG. 8, the same or corresponding portions to those in FIG. 1 are denoted by the same reference signs, and description thereof is omitted.

The TCO compensation circuit 7 causes a reference voltage VREF2 that cancels a fluctuation of an offset voltage of a sensor output that appears in response to a change in ambient temperature to be input to a reference voltage terminal of the amplifier circuit 4 by referring to an ambient temperature detected by the temperature sensor circuit 11.

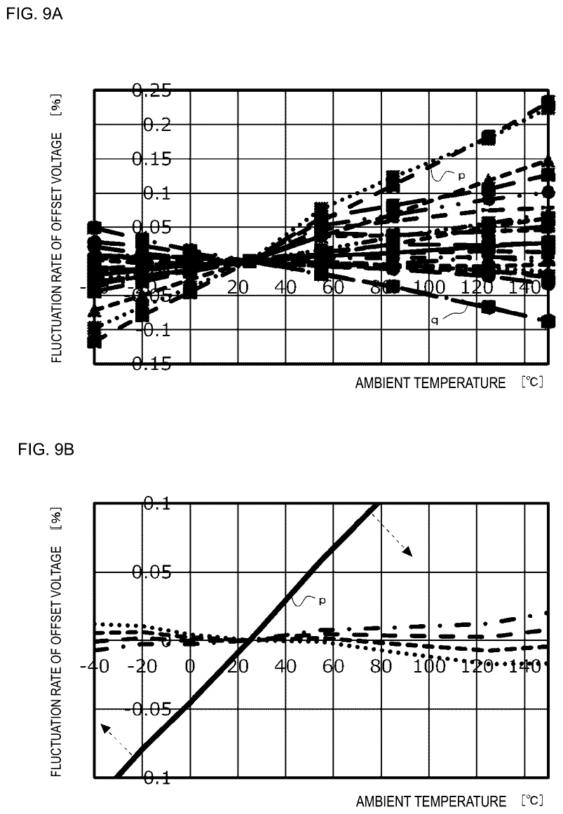

A temperature fluctuation of an offset voltage of a sensor output is illustrated in the graph of FIG. 9A. The horizontal axis of the graph represents an ambient temperature [° C.] of the sensor output compensation IC 1, and the vertical axis of the graph represents a fluctuation rate [%] of an offset voltage at each ambient temperature based on an offset voltage at an ambient temperature of, for example, about 25° C. Furthermore, the characteristic lines represent temperature characteristics of offset voltages regarding a plurality of TMR sensors 2. As indicated by the graph, temperature characteristics of each offset voltage are characteristics that linearly fluctuate with a linear slope. The TCO compensation circuit 7 causes the reference voltage VREF2 that cancels this fluctuation to be input to the reference voltage terminal that is the non-inverting input terminal of the operational amplifier 41 of the amplifier circuit 4.

In the present preferred embodiment, the TCO compensation circuit 7 includes a first inverting amplifier circuit 72 that includes an operational amplifier 71, a second inverting amplifier circuit 74 that includes an operational amplifier 73, a first switch 75, and a second switch 76.

The first inverting amplifier circuit 72 is configured such that a resistor R7 and a variable resistor R8 are connected to the operational amplifier 71, and a reference voltage VREF21 is provided to a non-inverting input terminal of the operational amplifier 71. The first inverting amplifier circuit 72 performs inverting amplification of an ambient temperature detected as a voltage by the temperature sensor circuit 11 at an amplification rate (R8/R7) corresponding to a fluctuation rate of an offset voltage. The fluctuation rate of the offset voltage corresponds to a slope of a characteristic line in the graph illustrated in FIG. 9A, and the amplification rate (R8/R7) is adjusted to the fluctuation rate of the offset voltage by adjustment of a resistance value of the variable resistor R8.

Furthermore, the second inverting amplifier circuit 74 is configured such that a resistor R9 and a variable resistor R10 are connected to the operational amplifier 73, and a reference voltage VREF22 is provided to a non-inverting input terminal of the operational amplifier 73. The second inverting amplifier circuit 74 performs inverting amplification of an output of the first inverting amplifier circuit 72 at an amplification rate (R10/R9) to invert a polarity thereof. The amplification rate (R10/R9) is set to approximately 1 by adjustment of a resistance value of the variable resistor R10. Furthermore, in a case where fluctuation of an offset voltage occurring in response to an ambient temperature is fluctuation that increases as the ambient temperature increases, the second switch 76 is controlled to close, and an output of the second inverting amplifier circuit 74 is input as the reference voltage VREF2 to the reference voltage terminal of the operational amplifier 41.

Therefore, in a case where temperature characteristics of an offset voltage of the sensor output compensation IC 1 are, for example, represented by the characteristic line p that is a straight line extending upward to the right indicating that fluctuation occurring in response to an ambient temperature increases as the ambient temperature increases in the graph illustrated in FIG. 9A, a voltage output from the temperature sensor circuit 11 represented by a characteristic line that is a straight line extending downward to the right indicating that fluctuation decreases as the ambient temperature increases is first converted into a voltage having a slope corresponding to the fluctuation rate of the offset voltage of the characteristic line p and whose slope polarity has been inverted to have characteristics extending upward to the right by the first inverting amplifier circuit 72 in the TCO compensation circuit 7. Then, since the second switch 76 is controlled to close, this voltage is converted into a reference voltage VREF2 whose slope polarity has been inverted to have characteristics extending downward to the right by the second inverting amplifier circuit 74. The amplifier circuit 4 amplifies an output voltage output from the differential amplifier circuit 3 that includes the offset voltage represented by the characteristic line p that is a straight line extending upward to the right based on the reference voltage VREF2, and thus the fluctuation of the offset voltage caused by the temperature characteristics is canceled.

FIG. 9B is a graph illustrating temperature characteristics of offset voltages of four TMR sensors 2 after compensation by the TCO compensation circuit 7. The horizontal axis and the vertical axis of the graph are the same as those in FIG. 9A. In the graph illustrated in FIG. 9B, the characteristic line p before compensation is illustrated, and temperature characteristics of an offset voltage regarding the TMR sensor 2 having the characteristic line p are adjusted to temperature characteristics whose slope has been flattened as indicated by the dotted-line arrows by the offset compensation to have an almost flat slope.

Furthermore, the first switch 75 is controlled to close in a case where fluctuation of an offset voltage occurring in response to an ambient temperature is fluctuation that decreases as the ambient temperature increases, and an output of the first inverting amplifier circuit 72 is input as the reference voltage VREF2 to the reference voltage terminal of the operational amplifier 41. Therefore, in a case where temperature characteristics of an offset voltage of the TMR sensor 2 is, for example, represented by the characteristic line q that is a straight line extending downward to the right indicating that fluctuation occurring in response to an ambient temperature decreases as the ambient temperature increases in the graph illustrated in FIG. 9A, a voltage output from the temperature sensor circuit 11 represented by a characteristic line that is a straight line extending downward to the right indicating that fluctuation decreases as the ambient temperature increases is converted into a reference voltage VREF2 having a slope corresponding to the fluctuation rate of the offset voltage of the characteristic line q and whose slope polarity has been inverted to have characteristics extending upward to the right by the first inverting amplifier circuit 72 in the TCO compensation circuit 7 since the first switch 75 is controlled to close. The amplifier circuit 4 amplifies an output voltage output from the differential amplifier circuit 3 that includes the offset voltage represented by the characteristic line q that is a straight line extending downward to the right based on the reference voltage VREF2, and thus the fluctuation of the offset voltage caused by the temperature characteristics is canceled as illustrated in the graph illustrated in FIG. 9B.

As described above, with the sensor output compensation IC 1 according to the present preferred embodiment, in a case where fluctuation of an offset voltage occurring in response to an ambient temperature is fluctuation that increases as the ambient temperature increases, the second switch 76 causes an output of the second inverting amplifier circuit 74 to be input to the reference voltage terminal of the amplifier circuit 4. Therefore, an ambient temperature detected as a voltage by the temperature sensor circuit 11 is inverted and amplified at the amplification rate (R8/R7) corresponding to a fluctuation rate of the offset voltage by the first inverting amplifier circuit 72 and is then subjected to polarity inversion by the second inverting amplifier circuit 74 to obtain an ambient temperature inverted signal that decreases at the fluctuation rate of the offset voltage as the ambient temperature increases, and this ambient temperature inverted signal is input as the reference voltage VREF2 to the reference voltage terminal of the operational amplifier 41 from the second inverting amplifier circuit 74. The amplifier circuit 4 amplifies an output of the differential amplifier circuit 3 based on the ambient temperature inverted signal, and thus a sensor output whose temperature fluctuation of an offset voltage has been canceled is obtained from the amplifier circuit 4.

Furthermore, in a case where fluctuation of an offset voltage occurring in response to an ambient temperature is fluctuation that decreases as the ambient temperature increases, the first switch 75 causes an output of the first inverting amplifier circuit 72 to be input to the reference voltage terminal of the operational amplifier 41. Therefore, an ambient temperature inverted signal that increases at a fluctuation rate of the offset voltage as the ambient temperature increases is obtained by inverting amplification at the amplification rate (R8/R7) corresponding to the fluctuation rate of the offset voltage by the first inverting amplifier circuit 72, and the ambient temperature inverted signal is input as the reference voltage VREF2 to the reference voltage terminal of the operational amplifier 41 from the first inverting amplifier circuit 72. The amplifier circuit 4 amplifies an output of the differential amplifier circuit 3 based on the ambient temperature inverted signal, and thus a sensor output whose fluctuation of an offset voltage appearing in response to a change in ambient temperature has been canceled is obtained from the amplifier circuit 4.

That is, with the sensor output compensation IC 1 according to the present preferred embodiment, the amplifier circuit 4 that adjusts an output of the differential amplifier circuit 3 amplifies an output of the differential amplifier circuit 3 based on the reference voltage VREF2 input to the reference voltage terminal of the operational amplifier 41 from the TCO compensation circuit 7, and thus fluctuation of an offset voltage of a sensor output that appears in response to a change in ambient temperature is canceled. Therefore, the offset voltage is adjusted easily with high accuracy by one compensation operation. Therefore, temperature compensation of an offset voltage of a sensor output can be easily and accurately performed unlike the conventional offset adjustment circuit disclosed in Japanese Unexamined Patent Application Publication No. 11-194160 that performs offset adjustment of a sensor output just by adjusting a midpoint potential of a differential amplifier circuit output by a variable resistor.

Furthermore, with the sensor output compensation IC 1 according to the present preferred embodiment, the circuits that define the sensor output compensation circuit are mounted on a same IC. This reduces variations resulting from a difference in wiring between the circuits that define the sensor output compensation circuit and mounting of components that define each circuit. Therefore, each compensation of a sensor output by the sensor output compensation IC 1 is performed with high accuracy. Furthermore, all compensation functions can be mounted on the IC. Furthermore, each compensation can be performed with high accuracy for each TMR sensor 2 with a relatively simple circuit configuration by monitoring a sensor output of the TMR sensor 2 to be adjusted. Furthermore, as for compensation adjustment of each compensation circuit, a compensation value can be easily selected by selecting setting data written into the EEPROM 12.

Furthermore, the temperature sensor circuit 11 is mounted on the same IC as the other circuits that define the sensor output compensation circuit, and therefore a relative position between the temperature sensor circuit 11 and the other circuits is always constant. Therefore, an error between an ambient temperature detected by the temperature sensor circuit 11 and an ambient temperature of the other circuits becomes small. Furthermore, in a case where the temperature sensor circuit 11 is provided separately from the IC of the other circuits, no error occurs between an ambient temperature detected by the temperature sensor circuit 11 and an ambient temperature used by the IC, for example, due to a parasitic resistance component of a wiring connection portion that connects the temperature sensor circuit 11 and the IC by, for example, wire bonding. As a result, with the sensor output compensation IC 1 according to the present preferred embodiment, temperature compensation of sensor sensitivity and an offset voltage can be performed with high accuracy.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A sensor output compensation circuit comprising:
a differential amplifier circuit to amplify, as a sensor output, a differential voltage between detection voltages appearing in a pair of detection signal output terminals of a sensor in which sensor components whose resistance values change in accordance with a detected physical quantity are bridge-connected;
an amplifier circuit to adjust an output of the differential amplifier circuit; and
a linearity compensation circuit for the sensor output to change an amplification rate of the amplifier circuit to an amplification rate that cancels distortion appearing with non-linearity in the sensor output in response to a change of a physical amount.

2. The sensor output compensation circuit according to claim 1, wherein
the amplifier circuit is operable to change the amplification rate by changing a resistance value of a connected resistor;
the connected resistor is operable to change the resistance value by switching a connection between a plurality of resistors by a plurality of switches and changing a combined resistance value of the plurality of resistors; and
the linearity compensation circuit is operable to change the amplification rate of the amplifier circuit by switching the plurality of switches in accordance with a result of comparison between a plurality of preset reference voltages corresponding to sensor outputs according to physical quantities that cause predetermined distortions and the output of the differential amplifier circuit.

3. The sensor output compensation circuit according to claim 1, wherein the differential amplifier circuit, the amplifier circuit, and the linearity compensation circuit are mounted on a same integrated circuit.

4. The sensor output compensation circuit according to claim 1, wherein the sensor components are Tunneling Magneto-Resistive components.

5. A sensor output compensation circuit comprising:
a differential amplifier circuit to amplify, as a sensor output, a differential voltage between detection voltages appearing in a pair of detection signal output terminals of a sensor in which sensor components whose resistance values change in accordance with a detected physical quantity are bridge-connected;
an amplifier circuit to adjust an output of the differential amplifier circuit;
a temperature sensor circuit to detect an ambient temperature; and
a sensor sensitivity temperature characteristic compensation circuit to change an amplification rate of the amplifier circuit to an amplification rate that cancels fluctuation appearing in sensitivity of the sensor output in response to a change of the ambient temperature detected by the temperature sensor circuit based on the ambient temperature.

6. The sensor output compensation circuit according to claim 5, wherein
the amplifier circuit is operable to change the amplification rate by changing a resistance value of a connected resistor;
the connected resistor is operable to change the resistance value by switching connection between a plurality of resistors by a plurality of switches to change a combined resistance value of the plurality of resistors;
the sensor sensitivity temperature characteristic compensation circuit is operable to change the amplification rate of the amplifier circuit by switching the plurality of switches in accordance with a result of comparison between a plurality of preset reference voltages corresponding to voltages according to ambient temperatures that cause predetermined fluctuations and the ambient temperature detected as a voltage by the temperature sensor circuit.

7. The sensor output compensation circuit according to claim 5, wherein the differential amplifier circuit, the amplifier circuit, the temperature sensor circuit, and the sensor sensitivity temperature characteristic compensation circuit are mounted on a same integrated circuit.

8. The sensor output compensation circuit according to claim 5, wherein the sensor components are Tunneling Magneto-Resistive components.

9. A sensor output compensation circuit comprising:
a differential amplifier circuit to amplify, as a sensor output, a differential voltage between detection voltages appearing in a pair of detection signal output terminals of a sensor in which sensor components whose resistance values change in accordance with a detected physical quantity are bridge-connected;
an amplifier circuit to adjust an output of the differential amplifier circuit;
a temperature sensor circuit to detect an ambient temperature; and
an offset temperature characteristic compensation circuit to cause a reference voltage that cancels fluctuation of an offset voltage of the sensor output appearing in response to a change of the ambient temperature to be input to a reference voltage terminal of the amplifier circuit for compensation by referring to the ambient temperature detected by the temperature sensor circuit.

10. The sensor output compensation circuit according to claim 9, wherein
the offset temperature characteristic compensation circuit includes a first inverting amplifier circuit to perform inverting amplification of the ambient temperature detected as a voltage by the temperature sensor circuit at an amplification rate corresponding to a fluctuation rate of the offset voltage, a second inverting amplifier circuit to invert a polarity of an output of the first inverting amplifier circuit, a first switch to cause the output of the first inverting amplifier circuit to be input to the reference voltage terminal of the amplifier circuit where a fluctuation of the offset voltage occurring in response to the ambient temperature is fluctuation that decreases as the ambient temperature increases, and a second switch to cause an output of the second inverting amplifier circuit to be input to the reference voltage terminal of the amplifier circuit where the fluctuation of the offset voltage occurring in response to the ambient temperature is fluctuation that increases as the ambient temperature increases.

11. The sensor output compensation circuit according to claim 9, wherein the differential amplifier circuit, the amplifier circuit, the temperature sensor circuit, and the offset temperature characteristic compensation circuit are mounted on a same integrated circuit.

12. The sensor output compensation circuit according to claim 9, wherein the sensor components are Tunneling Magneto-Resistive components.
